(19) United States
(12) Patent Application Publication
(10) Pub. No.: US 2013/0002308 A1
(43) Pub. Date: Jan. 3, 2013

(54) DRIVE CIRCUIT

(75) Inventor: Hitoshi IRINO, Kanagawa (JP)

(73) Assignee: RENESAS ELECTRONICS CORPORATION, Kanagawa (JP)

(21) Appl. No.: 13/607,156

(22) Filed: Sep. 7, 2012

Related U.S. Application Data
(62) Division of application No. 12/779,386, filed on May 13, 2010.

(30) Foreign Application Priority Data
Jun. 10, 2009 (JP) 2009-139266

(51) Int. Cl. H03B 1/00

(52) U.S. Cl. 327/108

(57) ABSTRACT

A drive circuit that outputs low-voltage differential signals to an external load circuit, including: first and second nodes to which the external load circuit is connected; a first series circuit including first and second switching elements, connected in series using the first node as a common node; a second series circuit including third and fourth switching elements, connected in series using the second node as a common node; and a first current source that outputs a predetermined current to the first and second series circuits, in which a back gate of a transistor of a first conductivity type included in at least one of the first and third switching elements or the first current source is forward-biased.

### INCORPORATION BY REFERENCE

This application is a Divisional of U.S. patent application Ser. No. 12/779,386, filed May 13, 2010, which claims priority from Japanese Patent Application No. 2009-139266, filed on Jun. 10, 2009, the disclosure of which is incorporated herein in its entirety by reference.

### BACKGROUND

1. Field of the Invention

The present invention relates to a drive circuit.

2. Description of Related Art

Low-voltage differential signaling (LVDS) has been employed as an interface for high-speed transmission of small-amplitude signals in recent years. FIG. 7 shows a drive circuit 1 employing LVDS (hereafter referred to as an “LVDS drive circuit 1”) as a related-art example. As shown in FIG. 7, the LVDS drive circuit 1 includes PMOS transistors MP1 to MP4 and NMOS transistors MN1 to MN4.

For the PMOS transistor MP1, its source is connected to a power supply voltage VDD, its drain to a node A1, and its gate to a node A3. For the PMOS transistor MP4, its source is connected to a power supply voltage VDD, and its drain and gate to the node A3. For the NMOS transistor MN4, its drain is connected to the node A3, and its source to a ground voltage VSS. A predetermined bias voltage Vb is applied to the gate of the NMOS transistor MN4.

For the PMOS transistor MP2, its source is connected to the node A1, and its drain to an external output terminal Tout2. For the NMOS transistor MN2, its drain is connected to the external output terminal Tout2, and its source to a node A2. The gates of the PMOS transistor MP2 and NMOS transistor MN2 receive a control signal S2 from a control circuit (not shown).

For the PMOS transistor 3, its source is connected to the node A1, and its drain to an external output terminal Tout1. For the NMOS transistor MN3, its drain is connected to the external output terminal Tout1, and its source to the node A2. The gates of the PMOS transistor MP3 and NMOS transistor MN3 receive a control signal S1 from a control circuit (not shown).

For the NMOS transistor MN1, its drain is connected to the node A2, and its source to a ground voltage VSS. A predetermined bias voltage Vb is applied to the gate of the NMOS transistor MN1. The power supply voltage VDD is applied to the back gate terminals of the PMOS transistors MP1 and MP4. The ground voltage VSS is applied to the back gate terminals of the NMOS transistors MN1 to MN4.

A termination resistor of an external circuit represented equivalently by a resistor RT1 (hereafter referred to as a “termination resistor RT1”) is connected between the external output terminals Tout1 and Tout2.

The operation of the LVDS drive circuit 1 will be described briefly. The PMOS transistor MP1 and NMOS transistor MN1, in which a constant voltage is applied to their gates, function as current sources. The control signals S1 and S2 are high-level/low-level signals (differential signals) having different phases. For example, when the control signal S1 is at a low level and the control signal S2 is at a high level, the PMOS transistor MP3 and NMOS transistor MN2 are on and the PMOS transistor MP2 and NMOS transistor MN3 are off. Accordingly, a current passes through a current path P1 indicated by the solid line in FIG. 7, more specifically, passes through the node A1, PMOS transistor MP3, termination resistor RT1, NMOS transistor MN2, and node A2. At that time, the external circuit receives a high-level LVDS signal, since the potential of the end adjacent to the external output terminal Tout1, of the termination resistor RT1 is higher than that of the end thereof adjacent to the external output terminal Tout2.

In contrast, when the control signal S1 is at a high level and the control signal S2 is at a low level, the PMOS transistor MP3 and NMOS transistor MN2 are off and the PMOS transistor MP2 and NMOS transistor MN3 are on. Accordingly, a current passes through a current path P2 indicated by the dotted line of FIG. 7, more specifically, passes through the node A1, PMOS transistor MP2, termination resistor RT1, NMOS transistor MN3, and node A2. At that time, the external circuit receives a low-level LVDS signal, since the potential of the end adjacent to the external output terminal Tout1, of the termination resistor RT1 is lower than that of the end thereof adjacent to the external output terminal Tout2.

Unfortunately, the LVDS drive circuit 1 thus configured has the following problems. The PMOS transistor MP4 forms a current mirror with the PMOS transistor MP1. Since the PMOS transistor MP1 operates as a current source, the PMOS transistor MP4 forming the current mirror therewith also operates in the saturation region. Accordingly, the operating voltage of the PMOS transistor MP4 and the NMOS transistor MN4 connected thereto in series is represented by Formula (1) below.

Vdsat_{MP4}+Vth_{MP4}+Vdsat_{MN4}<VDD−VSS Formula (1)

where Vdsat_{MP4} represents the saturation voltage of the PMOS transistor MP4, Vdsat_{MN4} represents the saturation voltage of the NMOS transistor MN4, and Vth_{MP4} represents the threshold voltage of the PMOS transistor MP4.

The value of the PMOS transistor MP4 depends on the manufacturing process. In general, the value of Vth_{MP4} increases as the voltage resistance of the gate oxide film increases. Since LVDS is an interface with an external circuit, a large current often passes through the component transistors and therefore transistors having high voltage resistance are often used as the component transistors. Accordingly, Vth_{MP4} has the largest proportion of the left side of Formula (1). Unless the value of Vth_{MP4} is reduced, the power supply voltage VDD is difficult to reduce.

Technology for reducing the power supply voltage VDD is disclosed in Japanese Unexamined Patent Application Publication No. 2008-54034. As a prior-art example, FIG. 8 shows a simplified configuration of a circuit described in Japanese Unexamined Patent Application Publication No. 2008-54034. As shown in FIG. 8, a drive circuit 2 employing LVDS (hereafter referred to as an “LVDS drive circuit 2”) described in Japanese Unexamined Patent Application Publication No. 2008-54034 does not include transistors corresponding to the PMOS transistor MP1 and NMOS transistor MN1 of FIG. 7. When the PMOS transistors MP2 and MP3 are on, a bias voltage is applied to their gates by a bias voltage supply circuit 11 via switching circuits SW11 to SW14. When the PMOS transistors MP2 and MP3 are off, the power supply voltage VDD is applied to the gates via these switching circuits. Similarly, when the NMOS transistors MN2 and MN3 are on, a bias voltage is applied to their gates by a bias voltage supply circuit 12 via switching circuits SW15 to SW18. When the NMOS transistors MN2 and MN3 are off, the ground voltage VSS is applied to the gates via these switching circuits. Accordingly, the LVDS drive circuit 2 does not include the PMOS transistor MP1 nor the PMOS transistor MP4 forming a current mirror therewith.

When a bias voltage is applied to their gates, the PMOS transistors MP2 and MP3 and NMOS transistors MN2 and MN3 operate as current sources and output a predetermined output current Iout. As in the LVDS drive circuit 1, the output current Iout makes a potential difference between both ends of the termination resistor RT1 of the external circuit, and the external circuit uses a logic signal corresponding to the potential difference, as an LVDS signal.

The LVDS drive circuit 2 thus configured does not include transistors corresponding to the PMOS transistor MP1 and NMOS transistor MN1 of FIG. 7. Accordingly, the power supply voltage VDD can be reduced by a voltage drop that would be caused by the PMOS transistor MP1 and NMOS transistor MN1 if the LVDS drive circuit 2 included these transistors. Also, the problem pointed out with respect to Formula (1) does not occur.

### SUMMARY

The LVDS drive circuit 2 includes the switching circuits SW11 to SW18, and transistors are used to realize these switching circuits The RC time constant obtained from the on-resistance of these transistors and the gate capacitance of the PMOS transistors MP2 and MP3 and NMOS transistors MN2 and MN3 restricts the speed at which these MOS transistors are turned on. This may dull the rising and falling waveforms of LVDS signals, failing to satisfy the rising and falling times determined by LVDS. As seen, the operating speed of the LVDS drive circuit 2 may decrease due to the RC time constant of the switching circuits.

Incidentally, in the LVDS drive circuit 2, the PMOS transistors MP2 and MP3 and NMOS transistors MN2 and MN3 operate as current sources. The PMOS transistors MP2 and MP3 are connected to the power supply voltage terminal VDD, and the NMOS transistors MN2 and MN3 are connected to the ground voltage terminal VSS. Accordingly, a constant current passed by the PMOS transistors MP2 and MP3 and NMOS transistors MN2 and MN3 when these MOS transistors are on is susceptible to power supply noise. In order to enhance resistance against power supply noise, it is necessary to increase a gate length L of the PMOS transistors MP2 and MP3 and NMOS transistors MN2 and MN3. An increase in gate length L, however, increases the gate capacitance. This reduces a conductance gm of the transistors and thus increases the rising time when they are on or the falling time when there are off, again resulting in a reduction in the operating speed of the LVDS drive circuit.

A first exemplary aspect of the present invention is a drive circuit that outputs low-voltage differential signals to an external load circuit, the drive circuit including: first and second nodes to which the external load circuit is connected; a first series circuit including first and second switching elements, the first and second switching elements being connected in series using the first node as a common node; a second series circuit including third and fourth switching elements, the third and fourth switching elements being connected in series using the second node as a common node; and a first current source that outputs a predetermined current to the first and second series circuits, in which a back gate of a transistor of a first conductivity type included in at least one of the first and third switching elements and the first current source is forward-biased.

In the drive circuit according to the exemplary aspect of the present invention, the back gate of the transistor of the first conductivity type included in at least one of first and second switching elements and the first current source is forward-biased. This can reduce the threshold voltage of the first conductivity-type transistor, thereby reducing the on-resistance of the first and second switching elements or the saturation voltage of the first current source. Thus, it is possible to reduce the operating voltage while avoiding the operating speed problem from occurring due to use of the switching circuits.

The drive circuit according to the exemplary aspect of the present invention can reduce the power supply voltage while preventing reductions in operating speed.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 shows the configuration of an LVDS drive circuit according to a first embodiment of the present invention;

FIG. 2 shows the configuration of an LVDS drive circuit according to a second embodiment of the present invention;

FIG. 3 shows the configuration of an LVDS drive circuit according to the second embodiment of the present invention;

FIG. 4 shows the configuration of an LVDS drive circuit according to a third embodiment of the present invention;

FIG. 5 shows the configuration of an LVDS drive circuit according to the third embodiment of the present invention;

FIG. 6 shows the configuration of an LVDS drive circuit according to another embodiment of the present invention;

FIG. 7 shows the configuration of an LVDS drive circuit in related art; and

FIG. 8 shows the configuration of an LVDS drive circuit in prior art.

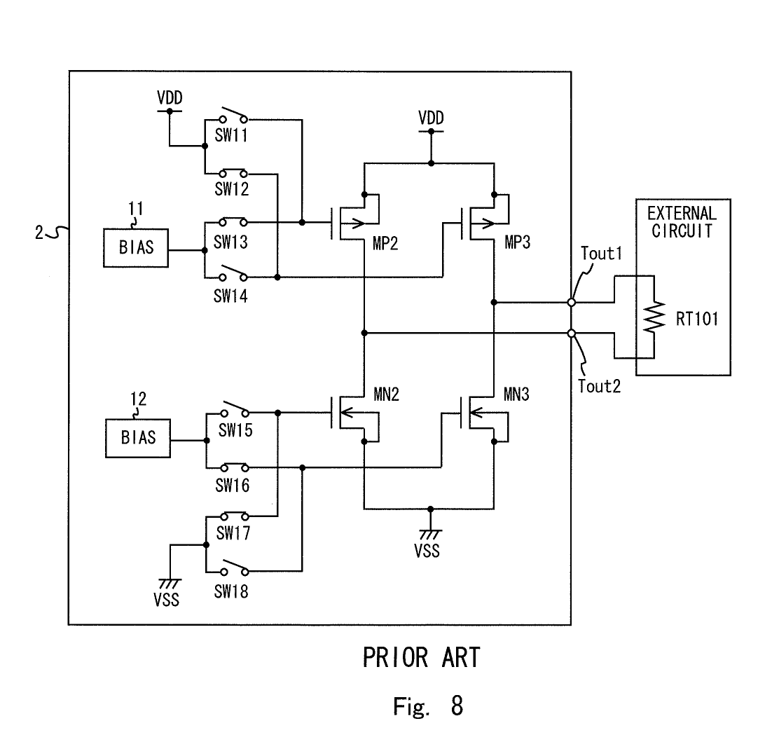

### DETAILED DESCRIPTION OF THE EXEMPLARY EMBODIMENTS

### First Embodiment

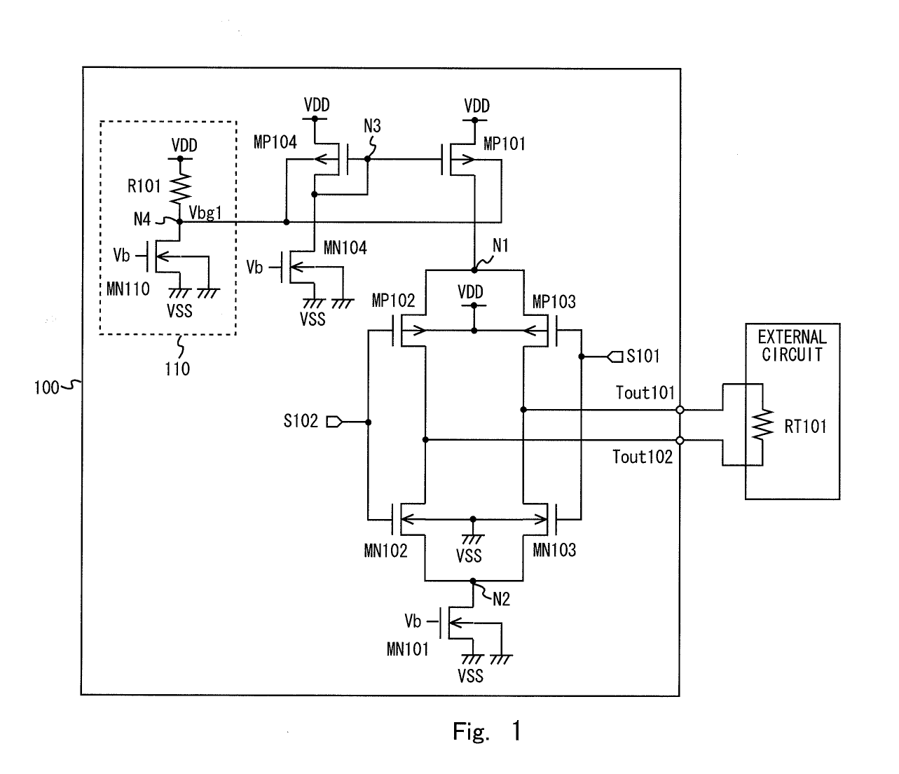

Now, a first embodiment of the present invention will be described in detail with reference to the accompanying drawings. The first embodiment is formed by applying the present invention to a drive circuit employing LVDS (hereafter referred to as an “LVDS drive circuit”). FIG. 1 shows the configuration of an LVDS drive circuit 100 according to the first embodiment.

As shown in FIG. 1, the LVDS drive circuit 100 includes PMOS transistors MP101 to MP104, NMOS transistors MN101 to MN104, and a bias voltage generation unit 110.

For the PMOS transistor MP101, its source is connected to a power supply voltage terminal VDD, its drain to a node N1, and its gate to a node N3. For the PMOS transistor MP104, its source is connected to a power supply voltage terminal VDD, and its drain and gate to the node N3. For the NMOS transistor MN104, its drain is connected to the node N3, and its source to a ground voltage terminal VSS. A predetermined bias voltage Vb is applied to the gate of the NMOS transistor MN104.

The PMOS transistors MP101 and MP104 form a current mirror using the PMOS transistor MP104 as an input transistor. Accordingly, a mirror current corresponding to a current passing through the PMOS transistor MP104 passes through the PMOS transistor MP101. For this reason, the PMOS transistors MP101 and MP104 and NMOS transistor MN104 form a current source that outputs an output current to the node N1. The back gate terminals of the PMOS transistors MP101 and MP104 are connected to a node N4.

The bias voltage generation unit 110 includes a resistor R101 and an NMOS transistor MN110. For the resistor R101, one terminal thereof is connected to a power supply voltage terminal VDD, and the other terminal to the node N4. For the NMOS transistor MN110, its drain is connected to the node N4, and its source to a ground voltage terminal VSS. A predetermined bias voltage Vb is applied to the gate of the NMOS transistor MN110. The NMOS transistor MN110 operates as a current source. Accordingly, the power supply voltage VDD is dropped by the resistor R101 by a predetermined potential and then applied to the node N4. This voltage applied to the node N4 is referred to as a bias voltage Vbg1. That is, the above-mentioned bias voltage Vbg1 is applied to the back gates of the PMOS transistors MP101 and MP104. Alternatively, the NMOS transistor MN110 may be replaced with a resistor.

For the PMOS transistor MP102, its source is connected to the node N1, and its drain to an external output terminal Tout102. For the NMOS transistor MN102, its drain is connected to an external output terminal Tout102, and its source to a node N2. The gates of the PMOS transistor MP102 and NMOS transistor MN102 receive a control signal S102 from a control circuit (not shown).

For the PMOS transistor MP103, its source is connected to the node N1, and its drain to an external output terminal Tout101. For the NMOS transistor MN103, its drain is connected to the external output terminal Tout101, and its source to the node N2. The gates of the PMOS transistor MP103 and NMOS transistor MN103 receive a control signal S101 from a control circuit (not shown). A power supply voltage VDD is applied to the back gates of the PMOS transistors MP102 and MP103. The PMOS transistors MP102 and MP103 and NMOS transistors MN102 and MN103 function as switching elements.

For the NMOS transistor MN101, its drain is connected to the node N2, and its source to a ground voltage terminal VSS. A predetermined bias voltage Vb is applied to the gate of the NMOS transistor MN101.

Connected between the external output terminals Tout101 and Tout102 is a termination resistor of an external circuit represented equivalently by a resistor RT101 (hereafter referred to as a “termination resistor RT101”).

The operation of the LVDS drive circuit 100 will be described briefly. The PMOS transistor MP101 and NMOS transistor MN101 function as current sources. The control signals S101 and S102 are high-level or low-level signals (differential signals) having different phases. For example, when the control signal S101 is at a low level and the control signal S102 is at a high level, the PMOS transistor MP103 and NMOS transistor MN102 are on and the PMOS transistor MP102 and NMOS transistor MN103 are off. Accordingly, a current passes through the node N1, PMOS transistor MP103, termination resistor RT101, NMOS transistor MN102, and node N2. At that time, the termination resistor RT101 of the external load circuit receives the current as a high-level LVDS signal, since the potential of the end adjacent to the external output terminal Tout101, of the termination resistor RT101 is higher than that of the end thereof adjacent to the external output terminal Tout102.

In contrast, when the control signal S101 is at a high level and the control signal S102 is at a low level, the PMOS transistor MP103 and NMOS transistor MN102 are off and the PMOS transistor MP102 and NMOS transistor MN103 are on. Accordingly, a current passes through the node N1, PMOS transistor MP102, termination resistor RT101, NMOS transistor MN103, and node N2. At that time, the termination resistor RT101 of the external load circuit receives the current as a low-level LVDS signal, since the potential of the end adjacent to the external output terminal Tout101, of the termination resistor RT101 is lower than that of the end thereof adjacent to the external output terminal Tout102.

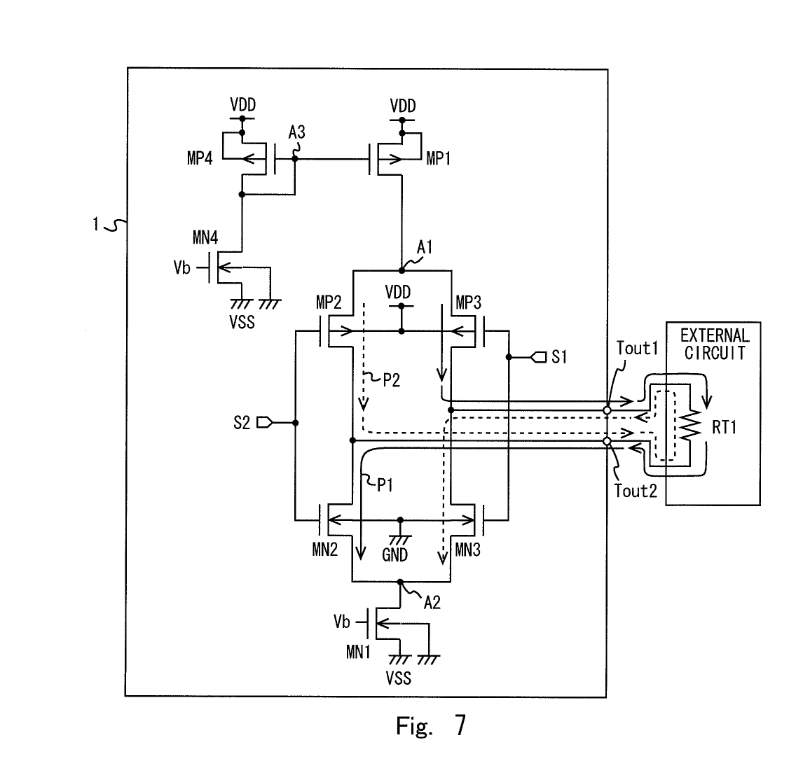

As seen, the basic operation of the LVDS drive circuit 100 is the same as that of the LVDS drive circuit 1 of FIG. 7. The PMOS transistor MP101 operates as a current source that outputs a constant current to the node N1. The PMOS transistor MP101 and PMOS transistor MP104 forming a current mirror therewith must operate in the saturation region, like the PMOS transistors MP1 and MP4 of the LVDS drive circuit 1. Unlike in the LVDS drive circuit 1, however, the back gates of the PMOS transistors MP101 and MP104 corresponding to the PMOS transistors MP1 and MP4 receive application of the bias voltage Vbg1. As described above, the bias voltage Vbg1 is a voltage obtained by reducing the power supply voltage VDD by a predetermined potential. That is, the back gates of the PMOS transistors MP101 and MP104 are forward-biased. Note that the bias voltage Vbg1 is a voltage such that a leak current does not flow between the source and back gate.

Incidentally, it is pointed out that the large value of the Vth_{MP4} is one of the reasons why the related-art LVDS drive circuit 1 cannot reduce the power supply voltage VDD. On the other hand, in the LVDS drive circuit 100, the bias voltage Vbg1 obtained by reducing the power supply voltage VDD by a predetermined potential is applied to the back gates of the PMOS transistors MP101 and MP104. The operating voltage of the PMOS transistor MP104 and NMOS transistor MN104 connected thereto in series is represented by Formula (2) below.

Vdsat_{MP104}+Vth_{MP104}−ΔVth_{MP104}+Vdsat_{MN104}<VDD−VSS Formula (2)

where Vdsat_{MP104} represents the saturation voltage of the PMOS transistor MP104, Vdsat_{MN104} represents the saturation voltage of the NMOS transistor MN104, Vth_{MP4} represents the threshold voltage of the PMOS transistor MP4, and ΔVth_{MP104} represents a variation in threshold voltage caused by application of the bias voltage Vbg1 to the back gate of the PMOS transistor MP104.

In the LVDS drive circuit 1, the n-well potential of the PMOS transistor MP4 is the power supply voltage VDD. Accordingly, the n-well potential of the PMOS transistor MP4 is the same potential as the source voltage, and the operating voltage of the PMOS transistor MP4 and NMOS transistor MN4 is represented by Formula (1).

On the other hand, in the LVDS drive circuit 100, the n-well potential of the PMOS transistor MP104 is not the power supply voltage VDD but the bias voltage Vbg1, which is lower than the power supply voltage VDD by a predetermined potential. Accordingly, the threshold voltage of the PMOS transistor MP104 is lower than the n-well potential identical to the source voltage, by the above-mentioned ΔVth_{MP104}. Accordingly, as shown in the left side of Formula (2), the operating voltage of the LVDS drive circuit 100 can be reduced by ΔVth_{MP104}. That is, the power supply voltage VDD can be reduced by ΔVth_{MP104}.

Thus, there is no need to use switch circuits to reduce the power supply voltage VDD as in the LVDS drive circuit 2, nor is there a need to consider delays in the on-operation of the transistors caused by the above-mentioned RC time constant. Also, in the LVDS drive circuit 2, the gate length L of the PMOS transistors MP2 and MP3 and NMOS transistors MN2 and MN3 must be increased to reduce the effect of power supply noise. On the other hand, in the LVDS drive circuit 100, the PMOS transistors MP102 and MP103 and NMOS transistors MN102 and MN103 simply function as switching elements. Thus, there is no need to increase the gate length L of the PMOS transistors MP102 and MP103 and NMOS transistors MN102 and MN103 in order to reduce the effect of power supply noise. This prevents occurrence of the operating speed reduction problem with the LVDS drive circuit 2. Also, an increase in the gate length L of transistors increases the size of the transistors, resulting in an increase in circuit size; the LVDS drive circuit 100 does not cause such a problem.

### Second Embodiment

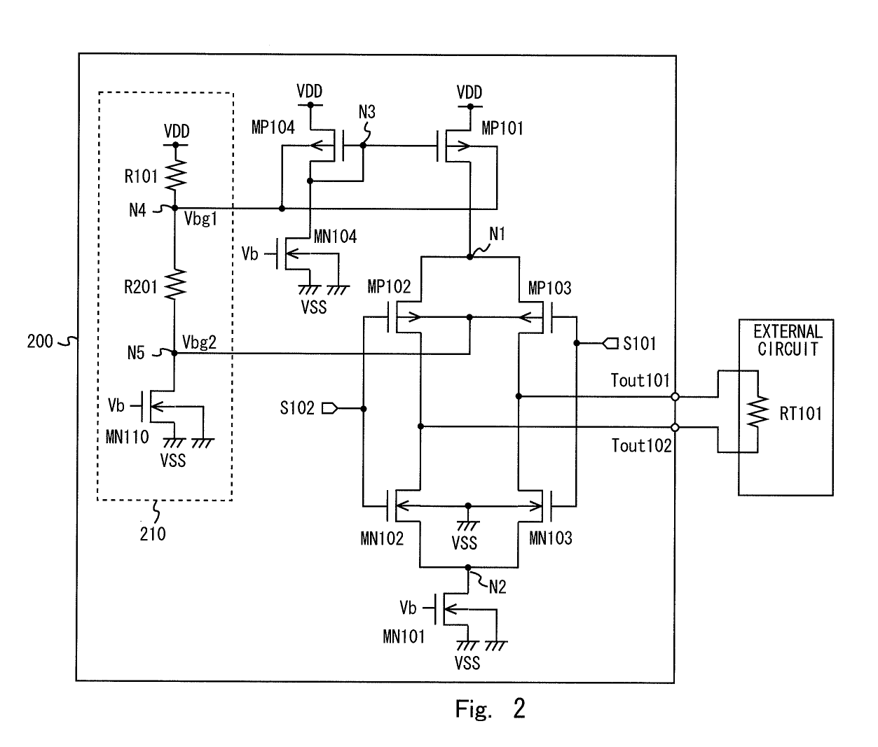

Now, a second embodiment of the present invention will be described in detail with reference to the accompanying drawings. As with the first embodiment, the second embodiment is formed by applying the present invention to an LVDS drive circuit. FIG. 2 shows the configuration of an LVDS drive circuit 200 according to the second embodiment.

As shown in FIG. 2, the LVDS drive circuit 200 includes PMOS transistors MP101, MP104, MP102, and MP103, NMOS transistors MN101 to MN104, and a bias voltage generation unit 210. Of the reference numerals shown in FIG. 2, the elements given the same reference numerals as those shown in FIG. 1 represent elements identical or similar to those shown in FIG. 1.

The differences between the second and first embodiments are the back gate potential of the PMOS transistors MP102 and MP103 and the bias voltage generation unit 210. These differences will be focused on in the following description and the same elements as those in the first embodiment will not be described.

The bias voltage generation unit 210 includes resistors R101 and R201 and an NMOS transistor MN110. For the resistor R101, one terminal thereof is connected to a power supply voltage terminal VDD, and the other terminal to a node N4. For the resistor 8201, one terminal thereof is connected to the node 4, and the other terminal to a node N5. For the NMOS transistor MN110, its drain is connected to the node N5, and its source to a ground voltage terminal VSS. A predetermined bias voltage Vb is applied to the gate of the NMOS transistor MN110.

The difference between the bias voltage generation units 210 and 110 is that the resistor R201 is connected between the other terminal of the resistor R101 and the drain of the NMOS transistor MN110. Accordingly, the power supply voltage VDD is dropped by the combined resistance of the resistors R101 and R201 by a predetermined potential and then applied to the node N5. This voltage applied to the node N5 is referred to as a bias voltage Vbg2.

For the PMOS transistor MP102, its source is connected to a node N1, and its drain to an external output terminal Tout102. Its gate receives a control signal S102. For the PMOS transistor MP102, its source is connected to the node N1, and its drain to an external output terminal Tout101. Its gate receives a control signal S101. The back gates of the PMOS transistors MP102 and MP103 are connected to the node N5.

While the power supply voltage VDD is applied to the back gates of the PMOS transistors MP102 and MP103 according to the first embodiment, a bias voltage Vbg2, obtained by reducing the power supply voltage VDD by a predetermined potential, is applied to those of the PMOS transistors MP102 and MP103 according to the second embodiment. This means that the back gate voltage of the PMOS transistors MP102 and MP103 is a forward bias. Note that the bias voltage Vbg2 is a voltage such that a leak current does not flow between the source and back gate.

The operation that the above-mentioned LVDS drive circuit 200 performs on the control signals S101 and S102 is basically the same as that of the LVDS drive circuit 100 and will not be described.

In general, an on-resistance Ron of an MOS transistor that operates in the linear region is represented by Formula (3) below.

Ron=1/(μ·C0·W/L·(Vgs−Vth)) Formula (3)

where μ represents carrier mobility, C0 represents the gate oxide film capacitance per unit area, W represents the gate width, L represents the gate length, Vgs represents the gate-source voltage, and Vth represents the threshold voltage.

As is understood from Formula (3), the value of the on-resistance Ron decreases as the threshold voltage Vth decreases.

Consider an on-resistance Ron1 of the PMOS transistor MP102 of the LVDS drive circuit 100 according to the first embodiment. The on-resistance Ron1 of the PMOS transistor MP102 is obtained from Formula (3) as follows:

Ron1=1/(μp·C0·W/L·(Vgs−Vth_{MP102}))

where Vth_{MP102} represents the threshold voltage of the PMOS transistor MP102 and μp represents the hall carrier mobility.

On the other hand, the bias voltage Vbg2 is provided to the back gate of the PMOS transistor MP102 according to the second embodiment. That is, a forward bias is applied to the back gate of the PMOS transistor MP102. An on-resistance Ron2 of the PMOS transistor MP102 is obtained as follows:

Ron2=1/(μp·C0·W/L·(Vgs−(Vth_{MP102}−ΔVth_{MP102})))

where ΔVth_{MP102} represents a variation in threshold voltage of the PMOS transistor MP102 caused by application of the bias voltage Vbg2 to the back gate

From a comparison between Ron1 and Ron2, it is understood that the on-resistance Ron2 of the PMOS transistor MP2 according to the second embodiment is smaller than the on-resistance Ron1 by the value corresponding to the variation in threshold voltage, ΔVth_{MP102}.

Since the PMOS transistor MP101 and NMOS transistor MN101 function as current sources as described above, they operates in the saturation region. The operating voltage of the LVDS drive circuit 100 is obtained by Formula (4) below. Here, it is assumed that the control signal S101 is at a high level and the control signal S102 is at a low level.

Vdsat_{MP101}+(Ron_{MP103}+Ron_{MN103}+RT101)×Iout+Vdsat_{MN101}<VDD−VSS Formula (4)

where Vdsat_{MP101} represents the saturation voltage of the PMOS transistor MP101, Vdsat_{MN101} represents the saturation voltage of the NMOS transistor MN101, Iout represents the output current of the PMOS transistor MP101 and NMOS transistor MN101, Ron_{MP102} represents the on-resistance of the PMOS transistor MP102, and Ron_{MN103} represents the on-resistance of the PMOS transistor MP103.

The value of Ron_{MP102} shown in Formula (4) is the same as the value of Ron1 according to the first embodiment or Ron2 according to the second embodiment. From a comparison between the first and second embodiments with respect to the value of Ron_{MP102} shown in Formula (4), it is understood that Ron_{MP102} according to the second embodiment is smaller than that according to the first embodiment by the value corresponding to ΔVth_{MP102}. When the value of the on-resistance Ron_{MP102} decreases, the voltage drop caused by this resistance decreases. As a result, the operating voltage of the LVDS drive circuit 200 can be reduced by the value corresponding to the reduced Ron_{MP102}. That is, the power supply voltage VDD can be made lower than that in the first embodiment.

In the second embodiment, the bias voltage Vbg2 from the bias voltage generation unit 210 is applied to the back gates of the PMOS transistor MP103 as well as the PMOS transistor MP102. Accordingly, if ΔVth_{MP103}, which is a variation in threshold voltage caused by application of the bias voltage Vbg2 to the back gate of the PMOS transistor MP103, is the same value as ΔVth_{MP102}, the on-resistance of the PMOS transistor MP103 is also the same value as Ron2. The conductance gm of the PMOS transistors MP101 and MP103 can also be increased. This increases the operating speed of the transistors.

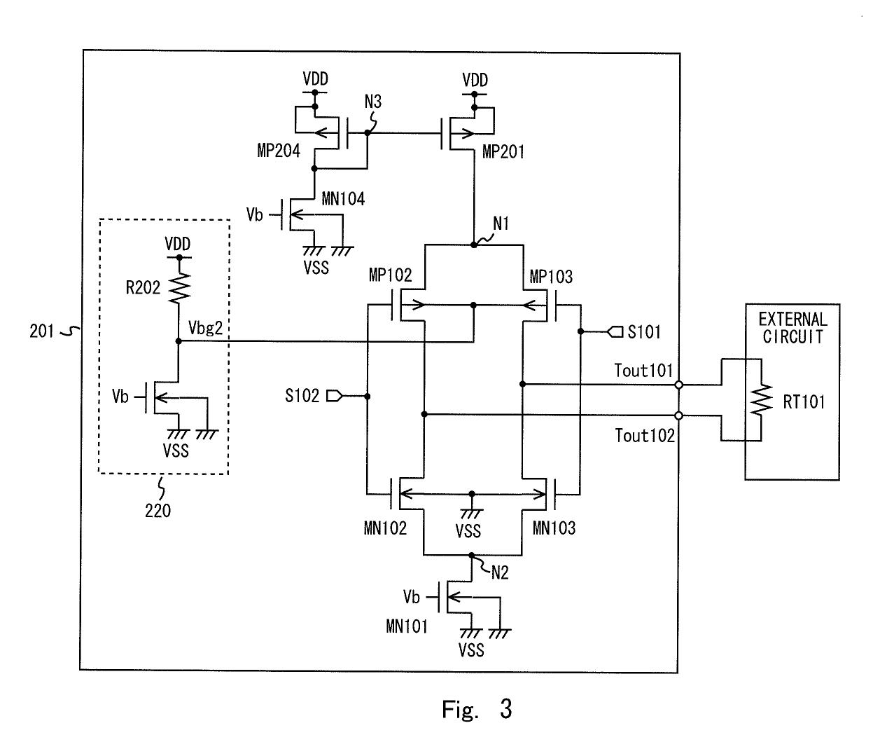

In the LVDS drive circuit 200 of FIG. 2, the bias voltage Vbg1 or Vbg2 is applied to the back gates of the PMOS transistors MP101 to MP104. Alternatively, as in an LVDS drive circuit 201 shown in FIG. 3, the bias voltage Vbg2 from a bias voltage generation unit 220 may be applied to only the back gates of PMOS transistors MP202 and MP203.

The bias voltage generation unit 220 includes a resistor R202 and an NMOS transistor MN110. The bias voltage generation unit 220 applies the bias voltage Vbg2 to the back gates of the PMOS transistors MP102 and MP103. The bias voltage Vbg2 is a voltage obtained when the resistor 8202 drops the power supply voltage VDD by a predetermined potential. That is, as in the LVDS drive circuit 200 of FIG. 2, the back gate voltage of the PMOS transistors MP202 and MP203 is a forward bias. The bias voltage Vbg2 is also a voltage such that a leak current does not flow between the source and back gate, as a matter of course.

### Third Embodiment

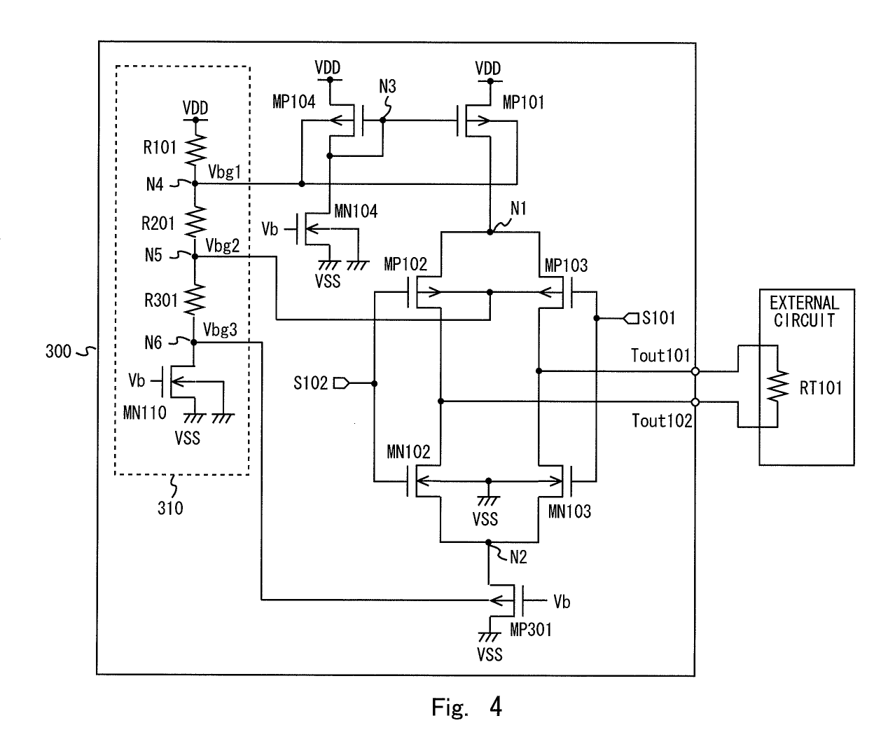

Now, a third embodiment of the present invention will be described in detail with reference to the accompanying drawings. As with the second embodiment, the third embodiment is formed by applying the present invention to an LVDS drive circuit. FIG. 4 shows the configuration of an LVDS drive circuit 300 according to the third embodiment.

As shown in FIG. 4, the LVDS drive circuit 300 includes PMOS transistors MP101, MP104, MP102, MP103, and MP301, NMOS transistors MN102 to MN104, and a bias voltage generation unit 310. Of the reference numerals shown in FIG. 4, the elements given the same reference numerals as those shown in FIG. 2 represent elements identical or similar to those shown in FIG. 2.

The differences between the third and second embodiments are the PMOS transistor MP301 and the bias voltage generation unit 310. The differences will be focused on in the following description and the same elements as those in the second embodiment will not be described.

The bias voltage generation unit 310 includes resistors R101, R201, and R301 and an NMOS transistor MN110. For the resistor R101, one terminal thereof is connected to a power supply voltage VDD, and the other terminal to a node N4. For the resistor R201, one terminal thereof is connected to the node 4, and the other terminal to a node N5. For the resistor R301, one terminal thereof is connected to the node 5, and the other terminal to a node N6. For the NMOS transistor MN110, its drain is connected to the node N6, and its source to a ground voltage VSS. A predetermined bias voltage Vb is applied to the gate of the NMOS transistor MN110.

The bias voltage generation unit 310 differs from the bias voltage generation unit 210 in that the resistor R301 is connected between the other terminal of the resistor 8201 and the drain of the NMOS transistor MN110. Accordingly, the power supply voltage VDD is reduced by the combined resistance of the resistors R101, R201, and R301 by a predetermined potential and then applied to the node N6. This voltage applied to the node N6 is referred to as a bias voltage Vbg3. The bias voltage Vbg3 is adjusted so that its value is lower than a potential Vn2 of the node N2. The potential of the node N6 can be easily adjusted, since the potential Vn2 of the node N2 is AC common.

For the PMOS transistor MP301, its source is connected to the node N2, and its drain to a ground voltage VSS. A predetermined bias voltage Vb is applied to its gate. Further, the bias voltage Vbg3 from the bias voltage generation unit 310 is applied to the back gate of the PMOS transistor MP301. As seen, in the LVDS drive circuit 300, the n-well potential of the PMOS transistor MP301 is the bias voltage Vbg3. Accordingly, the threshold voltage of the PMOS transistor MP3014 is lower than the n-well potential identical to the source voltage by ΔVth_{MP301}.

As with the MN101 according to the second embodiment, the PMOS transistor MP301 functions as a current source. The PMOS transistor MP301 also operates as a source follower circuit. The effect of using the PMOS transistor MP301 as a source follower circuit is that, even when power supply noise occurs in the power supply voltage VDD, a current passing through a termination resistor RT101 of an external circuit can be kept constant.

For example, an increase in the power supply voltage VDD due to power supply noise increases a gate-source voltage Vgs of the PMOS transistor MP101. Thus, the PMOS transistor MP101 attempts to increase the drain current. On the other hand, a current passing through the PMOS transistor MP301, which operates as a source follower circuit, makes almost no change. This allows keeping constant the current passing through the termination resistor RT101 of the external circuit, thereby keeping constant the center potential (common voltage) of the amplitude of LVDS signals that the external circuit receives. Note that, in order for the PMOS transistor MP301 to operate as a current source, the gate-source voltage Vgs must be kept at a given level or higher.

The operation that the above-mentioned LVDS drive circuit 300 performs on the control signals S101 and S102 is basically the same as that of the LVDS drive circuit 200 and will not be described.

As described above, the PMOS transistor MP301 passes a constant current as a current source. Accordingly, it must operate in the saturation region and its source-drain voltage Vds must be higher than a saturation voltage Vdsat of the MOS transistors.

The operating voltage of the LVDS drive circuit 300 is obtained by Formula (5) below. Here, it is assumed that the control signal S1 is at a high level and the control signal S2 is at a low level.

Vdsat_{MP101}+(Ron_{MP102}+Ron_{MN103}+RT101)×Iout+Vgs_{MP301}+Vb<VDD−VSS Formula (5)

where Vdsat_{MP101} represents the saturation voltage of the PMOS transistor MP101, Ron_{MP102} represents the on-resistance of the PMOS transistor MP102, Ron_{MN103} represents the on-resistance of the NMOS transistor MN103, Vgs_{MP301} represents the gate-source voltage of the PMOS transistor MP301, and Iout represents the output current of the PMOS transistors MP101 and MP301.

Further, Formula (5) is described as Formula (6) below.

Vdsat_{MP101}+(Ron_{MP102}+Ron_{MN103}+RT101)×Iout+Vdsat_{MP301}+Vth_{MP301}−ΔVth_{MP301}<VDD−VSS Formula (6)

where Vdsat_{MP301} represents the saturation voltage of the PMOS transistor MP301, Vth_{MP301} represents the threshold voltage, and ΔVth_{MP301} represents a variation in saturation voltage of the PMOS transistor MP301 due to application of the bias voltage Vbg3 to the back gate.

As described above, in order for the PMOS transistor MP301 to operate as a current source, its gate-source voltage Vgs must be kept at a given level or higher. Here, consider a case where the PMOS transistor MP301 is a normal PMOS transistor, whose back gate is reverse-biased. That is, consider a case where the back gate voltage (n-well potential) of the PMOS transistor MP301 is the same as its source voltage. In this case, its gate-source voltage Vgs must be kept at a given level or higher. This is disadvantageous in reducing the operating voltage of the LVDS drive circuit 300, compared with the second embodiment using the NMOS transistor MN101.

On the other hand, in the LVDS drive circuit 300 according to the third embodiment, the n-well potential of the PMOS transistor MP301 is the bias voltage Vbg3. Accordingly, as shown in Formula (6), the threshold voltage of the PMOS transistor MP301 can be made lower than the n-well potential identical to the source voltage by ΔVth_{MP301}. As a result, the LVDS drive circuit 300 can reduce the operating voltage, as well as can advantageously use the PMOS transistor MP301 as a source follower.

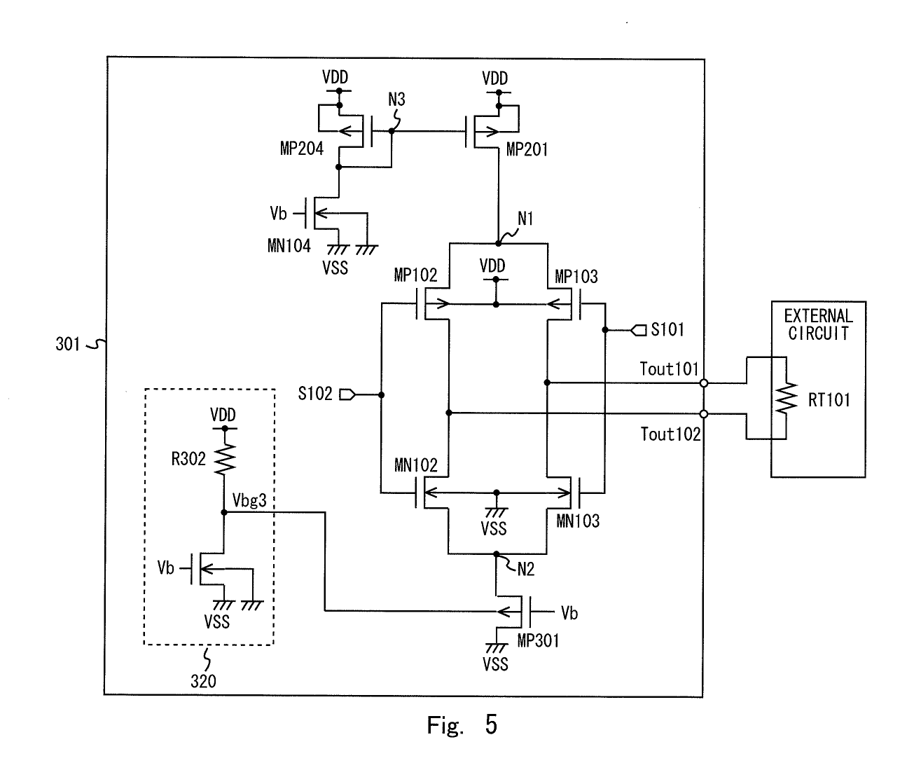

In the LVDS drive circuit 300 of FIG. 4, the bias voltage Vbg1, Vbg2, or Vbg3 are applied to the back gates of the PMOS transistors MP101 to MP104 and MP301. Alternatively, as in an LVDS drive circuit 301 of FIG. 5, a bias voltage Vbg3 from a bias voltage generation unit 320 may be applied to only the back gate of a PMOS transistor MP301.

The bias voltage generation unit 320 includes a resistor R302 and an NMOS transistor MN110. The bias voltage generation unit 320 applies the bias voltage Vbg3 to the back gate of the PMOS transistor MP301. The bias voltage Vbg3 is a voltage obtained when the resistor R302 drops the power supply voltage VDD by a predetermined potential. That is, as in the LVDS drive circuit 300, the back gate of the PMOS transistor MP301 is forward-biased. Note that the bias voltage Vbg3 is a voltage such that a leak current does not flow between the source and back gate.

The present invention is not limited to the above-mentioned embodiments and changes can be made thereto as appropriate without departing from the spirit and scope of the invention. For example, the conductivity types of the MOS transistors in the first to third embodiments may be reversed. Specifically, in the first to third embodiments, the back gate potential of the PMOS transistors is a voltage (forward bias) lower than the power supply voltage VDD by a predetermined potential. Alternatively, the back gate voltage of the NMOS transistors may be a voltage higher than the ground voltage VSS by a predetermined potential. In other words, the back gates of the NMOS transistors are forward-biased.

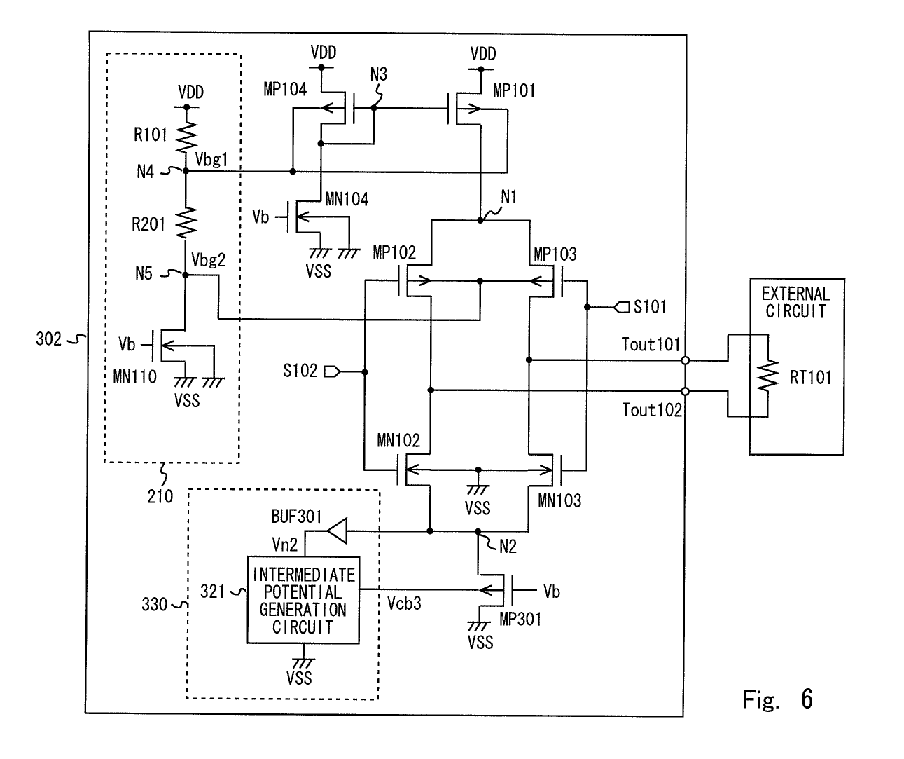

In the third embodiment, the back gate voltage of the PMOS transistor MP301 is generated in the bias voltage generation unit 310 or 320. Alternatively, the back gate voltage may be generated by way of other methods. For example, the back gate voltage may be generated in a bias voltage generation unit 330 of an LVDS drive circuit 302 as shown in FIG. 6.

The bias voltage generation unit 330 includes a buffer circuit BUF301 and an intermediate potential generation circuit 321. The buffer circuit BUF301 buffers a current and outputs the same potential as that of the node N2. The input impedance of the buffer circuit BUF301 is set to a sufficiently high value so as to prevent the connection of the buffer circuit BUF301 to the node N2 from affecting the potential Vn2 of the node N2. The intermediate potential generation circuit 321 generates a predetermined bias voltage Vbg3 between the potential Vn2 and ground voltage VSS.

As described above, the potential Vn2 of the node N2 is AC common. Accordingly, the potential Vn2 of the node N2 makes almost no change, namely, is a constant potential. More specifically, the potential Vn2 is a voltage obtained by reducing the power supply voltage VDD by a predetermined voltage. Further, the bias voltage Vbg3 obtained when the intermediate potential generation circuit 321 reduces the potential Vn2 by a predetermined potential is applied to the back gate of the PMOS transistor MP301. Accordingly, as in the LVDS drive circuit 300, the back gate of the PMOS transistor MP301 is forward-biased.

Alternatively, the bias voltage Vbg3 from the bias voltage generation unit 330 may be applied to only the back gate of the PMOS transistor MP301.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

The first to third exemplary embodiments can be combined as desirable by one of ordinary skill in the art.

What is claimed is:

1. A drive circuit that outputs low-voltage differential signals to an external load circuit, comprising:
first and second nodes to which the external load circuit is connected;
a first series circuit comprising first and second switching elements, connected in series using the first node as a common node;
a second series circuit comprising third and fourth switching elements, connected in series using the second node as a common node;
a first current source that outputs a predetermined current to the first and second series circuits, and
a transistor of the first conductivity type, functioning as a source follower, whose back gate is forward-biased,
wherein a back gate of a transistor of a first conductivity type included in at least one of the first and third switching elements or the first current source is forward-biased.

2. The drive circuit according to claim 1, further comprising:
a first power supply terminal that provides a first power supply voltage;
a second power supply terminal that provides a second power supply voltage; wherein
the first and second series circuits are connected in parallel between a third node and a fourth node,
the source follower is connected between the first power supply terminal and the third node,
the first current source is connected between the second power supply terminal and the third node, and
a voltage having a predetermined potential different from the first power supply voltage is applied to a back gate of the transistor.

3. The drive circuit according to claim 1, further comprising:
a first power supply terminal that provides a first power supply voltage;
a second power supply terminal that provides a second power supply voltage; wherein
the first and second series circuits are connected in parallel between a third node and a fourth node,
the second current source is connected between the first power supply terminal and the fourth node,
the first current source is connected between the second power supply terminal and the third node, and
a voltage having a predetermined potential different from a voltage of the third node is applied to a back gate of the transistor.
